(19) United States
(12) Patent Application Publication
(10) Pub. No.: US 2024/0305207 A1
(43) Pub. Date: Sep. 12, 2024

(54) CONTROL CIRCUIT FOR A RESONANT CIRCUIT AND THE METHOD THEREOF

(71) Applicant: Hangzhou MPS Semiconductor Technology, Ltd., Hangzhou (CN)

(72) Inventors: Pengfei Liu, Hangzhou (CN); Yuzhou Zhang, Hangzhou (CN)

(21) Appl. No.: 18/596,081

(22) Filed: Mar. 5, 2024

(30) Foreign Application Priority Data
Mar. 7, 2023 (CN) 202310239070.1

(51) Int. Cl. H02M 3/335; H02M 3/00; H03K 17/687

(52) U.S. Cl. CPC H02M 3/33571; H02M 3/01; H03K 17/687; H03K 2217/0063; H03K 2217/0072

(57) ABSTRACT

A control circuit for a resonant circuit having a high-side switch and a low-side switch is disclosed. The control circuit includes a low-side switch control circuit. The low-side switch control circuit provides a low-side switch control signal for controlling the low-side switch. The low-side switch control signal has a first pulse associated with a first on-time period of the low-side switch. An end of the first pulse of the low-side switch control signal corresponds to a time when a voltage across a resonant capacitor of the resonant circuit crosses zero from positive to negative.

### CROSS-REFERENCE TO RELATED APPLICATIONS

This application claims priority to and the benefit of Chinese Patent Application No. 202310239070.1, filed on Mar. 7, 2023, which is incorporated herein by reference in its entirety.

### FIELD

The present invention relates generally to switching power supplies, and more particularly but not exclusively to resonant circuits.

### BACKGROUND

The conventional flyback converter has been widely used for low-power electronics applications because of its low-cost and simple structure. However, the switch used in the flyback converter always works in hard-switching mode, i.e., the voltage across the switch and the current flowing through the switch are not zero at the moment when the switch is turned on/off, which results in high switching loss. As the switching power supplies are developing towards miniaturization, lightweight and modularization, the switching frequency is required to be increasing. As can be appreciated, the switching loss of the flyback converter increases as the switching frequency increases. Consequently, the flyback converter cannot be employed in high-power applications.

To overcome the drawbacks of the hard switching technique, soft switching technique is developed, which means the voltage across the switch or the current flowing through the switch is controlled to be zero or close to zero at the moment when the switch is turned on/off (i.e., zero-voltage-switching (ZVS) and zero-current-switching (ZCS)), to eliminate or reduce the switching loss. For flyback converters, resonant topologies (e.g., active-clamp flyback converters and asymmetrical half-bridge flyback converters) are incorporated to implement soft switching. The asymmetrical half-bridge flyback converter employs an LLC resonant topology at the primary side to realize resonant operation. Through proper control of the current's phase and amplitude, soft switching could be achieved in the flyback converter to reduce the switching loss.

### SUMMARY

According to an embodiment of the present invention, a control circuit for a resonant circuit having a high-side switch and a low-side switch is provided. The control circuit includes a low-side switch control circuit. The low-side switch control circuit provides a low-side switch control signal for controlling the low-side switch. The low-side switch control signal has a first pulse associated with a first on-time period of the low-side switch. An end of the first pulse of the low-side switch control signal corresponds to a time when a voltage across a resonant capacitor of the resonant circuit crosses zero from positive to negative.

According to an embodiment of the present invention, a resonant circuit is provided. The resonant circuit includes a high-side switch, a low-side switch, a high-side switch control circuit, and a low-side switch control circuit. The high-side switch control circuit provides a high-side switch control signal for controlling the high-side switch. The low-side switch control circuit provides a low-side switch control signal for controlling the low-side switch. The low-side switch control signal has a first pulse associated with a first on-time period of the low-side switch. An end of the first pulse of the low-side switch control signal corresponds to a time when a voltage across a resonant capacitor of the resonant circuit crosses zero from positive to negative.

According to another embodiment of the present invention, a control method for a resonant circuit having a high-side switch and a low-side switch is provided. The control method includes six main steps in each switching period of multiple switching periods. In step 1, turning on the low-side switch. In step 2, turning off the low-side switch when a pre-charge time period of the low-side switch ends, or a voltage across a resonant capacitor of the resonant circuit crosses zero from positive to negative. In step 3, turning on the high-side switch. In step 4, turning off the high-side switch when a current flowing through the resonant capacitor reaches a preset peak value. In step 5, turning on the low-side switch. In step 6, turning off the low-side switch when a transformer of the resonant circuit is demagnetized, or a resonance period of a resonant inductor and the resonant capacitor of the resonant circuit ends.

According to yet another embodiment of the present invention, a control circuit for a resonant circuit having a first switch, a second switch, and a transformer is provided. The transformer has a primary winding and a secondary winding, and a resonant capacitor coupled in series with the primary winding. The control circuit includes a first switch control circuit and a second switch control circuit. The first switch control circuit provides a first switch control signal for controlling the first switch. The first switch control circuit turns off the first switch when a current flowing through the resonant capacitor reaches a preset peak value. The second switch control circuit provides a second switch control signal for controlling the second switch. The second switch control circuit turns on the second switch based on a switching voltage at a connection node of the first switch and the second switch, and turns off the second switch when a voltage across the resonant capacitor crosses zero.

### BRIEF DESCRIPTION OF THE DRAWINGS

The present invention can be further understood with reference to the following detailed description and the appended drawings.

FIG. 1 schematically shows a conventional resonant circuit 10.

FIG. 2 schematically shows a conventional resonant circuit 20 with another structure.

FIG. 3 schematically shows a control circuit 30 in accordance with an embodiment of the present invention.

FIG. 4 schematically shows waveforms of signals of the resonant circuit 10 operating in PSM (pulse skipping mode) with a low output voltage Vout in accordance with an embodiment of the present invention.

FIG. 5 schematically shows waveforms of signals of the resonant circuit 10 operating in PSM with a high output voltage Vout in accordance with an embodiment of the present invention.

FIG. 6 schematically shows waveforms of signals of the resonant circuit 10 operating in CCM (continuous current mode) in accordance with an embodiment of the present invention.

FIG. 7 schematically shows a control circuit 70 in accordance with an embodiment of the present invention.

FIG. 8 schematically shows a flowchart of a control method 80 for a resonant circuit operating in PSM with the low output voltage Vout in accordance with an embodiment of the present invention.

FIG. 9 schematically shows a flowchart of a control method 90 for a resonant circuit operating in CCM in accordance with an embodiment of the present invention.

### DETAILED DESCRIPTION

Various embodiments of the present invention will be described in detail below, and it should be noted that the embodiments described here are only for illustration. However, the present invention is not limited thereto. In the following description, numerous specific details, such as example circuits and example values for these circuit components, and methods are illustrated in order to provide a thorough understanding of the present invention. It will be apparent for persons having ordinary skill in the art that the present invention can be practiced without one or more specific details, or with other methods, components, materials. In other instances, well-known circuits, materials or methods are not shown or described in detail in order to avoid obscuring the present invention.

Throughout this description, the phrases “in one embodiment”, “in an embodiment”, “in some embodiments”, “in an example”, “in some examples”, “in one implementation”, and “in some implementations” as used to include both combinations and sub-combinations of various features described herein as well as variations and modifications thereof. These phrases used herein does not necessarily refer to the same embodiment, although it may. Additionally, persons having ordinary skill in the art will understand that the drawings provided herein are for illustrative purposes and are not necessarily drawn to scale. The similar elements are provided with similar reference numerals. As used herein, the term “and/or” includes any combinations of one or more of the listed items.

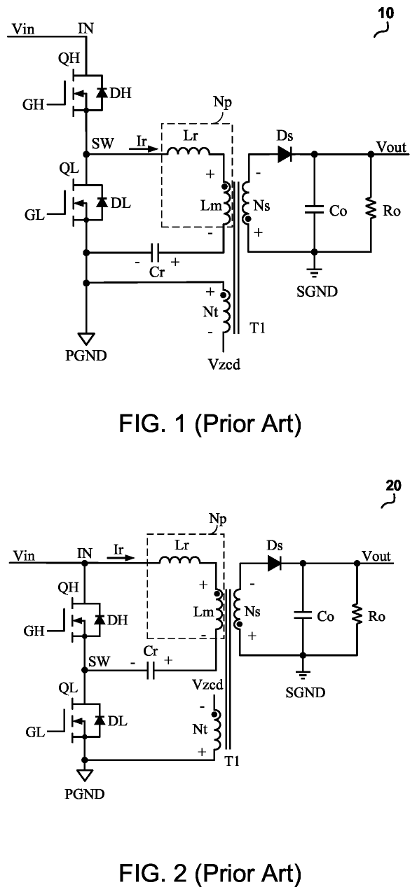

FIG. 1 schematically shows a conventional resonant circuit 10. As shown in FIG. 1, the resonant circuit 10 has an asymmetric half-bridge flyback converter topology, including a transformer T1, a primary side circuit and a secondary side circuit. The transformer T1 includes a primary winding Np, a secondary winding Ns and an auxiliary winding Nt. The primary side circuit includes a high-side switch QH, a low-side switch QL, and a resonant capacitor Cr. The high-side switch QH and the low-side switch QL are coupled in series between an input terminal IN and a primary ground terminal PGND. The resonant capacitor Cr and the primary winding Np are coupled in series with between a switching terminal SW and the primary ground terminal PGND. The secondary side circuit includes a secondary switch Ds, which is coupled in series with the secondary winding Ns and an output capacitor Co. In the embodiment as shown in FIG. 1, a resonant inductor Lr is a leakage inductance of the primary winding Np rather than an actual inductor. In some embodiments, additional inductors may be applied as resonant inductors according to practical applications. In one implementation, the secondary switch Ds is realized by a diode. In another implementation, the secondary switch Ds is realized by a controllable switch, e.g., MOSFET (Metal-oxide-semiconductor field effect transistor). In some embodiments, the secondary switch Ds is coupled between the secondary winding Ns and a secondary ground terminal SGND.

As shown in FIG. 1, an energy of the primary winding Np is transferred to the secondary winding Ns by alternately turning on/off the high-side switch QH and the low-side switch QL of the resonant circuit 10, such that an output voltage out across the output capacitor Co could be provided to power a load Ro. To be specific, when the high-side switch QH is turned on and the low-side switch QL is turned off, the energy stored in the inductor of the primary winding Np (e.g., the resonant inductor Lr) and the resonant capacitor Cr, and the load Ro is powered by the output capacitor Co. When the high-side switch QH is turned off and the low-side switch QL is turned on, the energy stored in the inductor of the primary winding Np and the resonant capacitor Cr is transferred to the second winding Ns to charge the output capacitor Co, such that the output voltage out across the output capacitor Co is provided to power the load Ro.

FIG. 2 schematically shows a conventional resonant circuit 20 with another structure. Compared with the resonant circuit 10 shown in FIG. 1, the resonant capacitor Cr and the primary winding Np of the resonant circuit 20 are coupled in series between the input terminal IN and the switching terminal SW. The resonant capacitor Cr and the primary winding Np are connected in parallel with the high-side switch QH.

As shown in FIG. 1 and FIG. 2, a half-bridge circuit including the high-side switch QH and the low-side switch QL is coupled between the input terminal IN and the primary ground terminal PGND. The input terminal IN is configured to receive an input voltage Vin. The input voltage Vin is a DC voltage which may be obtained by rectifying an AC voltage. Ir represents a resonant current (i.e., a current flowing through the resonant capacitor Cr), and a direction of an arrow shown in FIG. 1 is assumed to be a positive direction of the resonant current. The switching voltage Vsw refers to a voltage of a connection node of the high-side switch QH and the low-side switch QL (i.e., switching terminal SW). GH represents a high-side switch control signal of the high-side switch QH, and GL represents a low-side switch control signal of the low-side switch QL. In FIG. 1 and FIG. 2, the high-side switch QH and the low-side switch QL are realized by MOSFETs. It should be appreciated that, resonant circuits having other types of controllable switches also could be controlled by the control circuit in the embodiments of the present invention.

Parasitic capacitors are existed in the high-side switch QH, the low-side switch QL, and other devices of the resonant circuit. When a voltage difference across the high-side switch QH/low-side switch QL is existed, the parasitic capacitors would be charged/discharged at the moment when the high-side switch QH/the low-side switch QL is turned on, thereby generating turn-on loss. The present disclosure devotes to realize a ZVS turn-on of the switch to reduce turn-on loss. Control circuits in the embodiments of the present invention could be applied in the resonant circuits of FIG. 1 and FIG. 2, and other resonant circuits, such as LLC resonant circuits (i.e., a circuit including two inductors (L) and a capacitor (C)) and LCC resonant circuits (i.e., a circuit including an inductor (L) and two capacitors (C)).

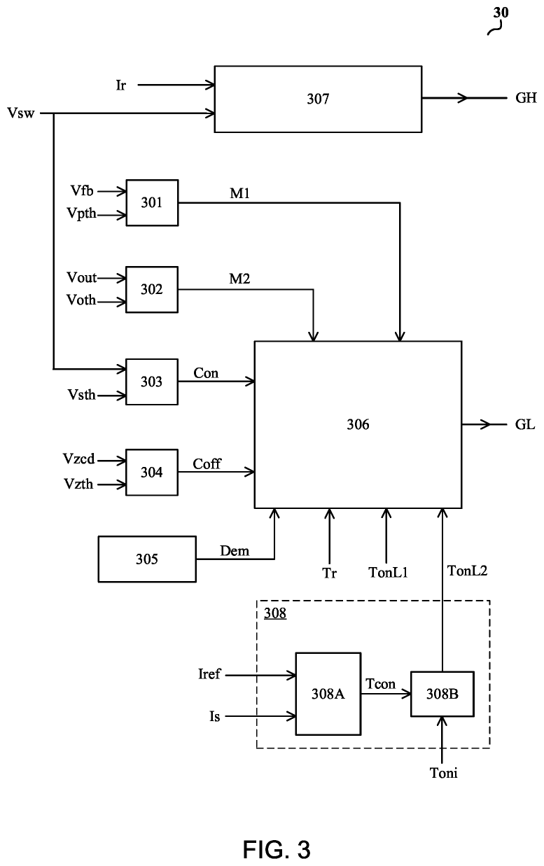

FIG. 3 schematically shows a control circuit 30 in accordance with an embodiment of the present invention. As shown in FIG. 3, the control circuit 30 includes an output power detecting circuit 301, an output voltage detecting circuit 302, a switching voltage detecting circuit 303, a zero-crossing detecting circuit 304, a demagnetization detecting circuit 305, a low-side switch control circuit 306, a high-side switch control circuit 307 and an on-time period control circuit 308.

In some embodiments, the control circuit 30 controls resonant circuits to operate in CCM (Continuous Conduction Mode) or PSM (Pulse Skip Mode) based on different operating conditions.

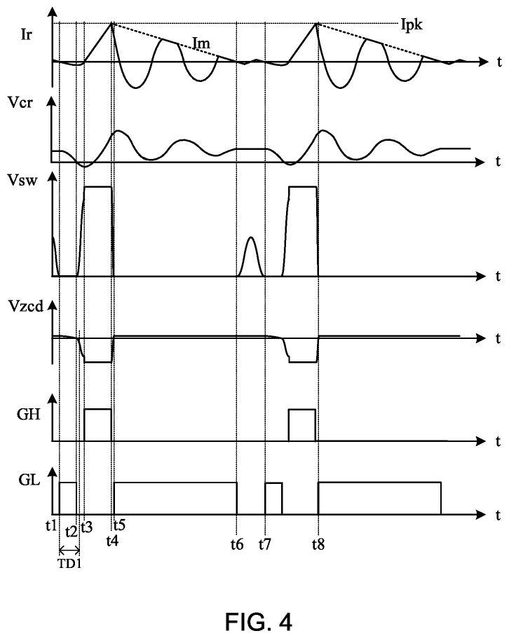

FIG. 4 schematically shows waveforms of signals of the resonant circuit 10 operating in PSM with a low output voltage out. Referring to FIG. 1, FIG. 3, and FIG. 4, the working principle of the control circuit 30 and a working process of the resonant circuit 10 operating in PSM with the low output voltage Vout are illustrated.

In FIG. 3, the output power detecting circuit 301 receives a power feedback signal Vfb and a power threshold Vpth, and provides an output power determining signal M1 based on the power feedback signal Vfb and the power threshold Vpth. The power feedback signal Vfb indicates an output power of the resonant circuit 10. In some embodiments, when the power feedback signal Vfb is smaller than the power threshold Vpth, the resonant circuit 10 is controlled by the control circuit 30 to operate in PSM, otherwise, the resonant circuit 10 is controlled to operate in CCM.

In FIG. 3, the output voltage detecting circuit 302 receives the output voltage Vout of the resonant circuit 10 and an output voltage threshold Voth, and provides an output voltage determining signal M2 based on the output voltage Vout and the output voltage threshold Voth.

FIG. 4 shows waveforms of signals of when the resonant circuit 10 operating in PSM with the low output voltage Vout, which means the output voltage Vout is lower than the output voltage threshold Voth, and the power feedback signal Vfb is smaller than the power threshold Vpth.

The switching voltage detecting circuit 303 receives the switching voltage Vsw and a switching voltage threshold Vsth, and provides a turn-on control signal Con based on a comparison result of the switching voltage Vsw and the switching voltage threshold Vsth. In one embodiment, the value of the switching threshold Vsth is equal to zero. As shown in FIG. 4, at time t1, the switching voltage Vsw decreases to zero. The turn-on control signal Con pulls up the low-side switch control signal GL through the low-side switch control circuit 306, to turn on the low-side switch QL. In other words, the low-side switch QL is turned on when the switching voltage Vsw decreases to zero, the ZVS turn-on of the low-side switch QL could be achieved, thereby reducing the turn-on loss of the low-side switch QL. In some embodiments, the value of the switching voltage threshold Vsth may be close to zero (i.e., slightly greater than zero or less than zero).

The zero-crossing detecting circuit 304 provides a turn-off control signal Coff based on a zero-crossing detecting signal Vzcd.

In the turn-on process of the low-side switch QL, the time when the zero-crossing detecting signal Vzcd is equal to zero indicates the time when the energy stored in the primary winding Np reaches to a maximum value. By turning off the low-side switch QL at the time when the energy stored in the primary winding Np reaches to a maximum value, the energy stored in the primary winding Np is transferred to the parasitic capacitor of the switching terminal SW. In this case, the transferred energy could pull up the switching voltage Vsw to its maximum value. Therefore, the voltage difference across the high-side switch QH is minimized and the turn-on loss of the high-side switch QH could be reduced.

In resonant circuits shown in FIG. 1 and FIG. 2, the zero-crossing detecting signal Vzcd indicates a voltage across the auxiliary winding Nt. In FIG. 1, when the low-side switch QL is turned on and a voltage across the resonant capacitor Vcr decreases to zero (i.e., time t2 shown in FIG. 4), the resonant current Ir reaches a minimum value (i.e., a negative maximum value). Due to the current flowing through the secondary winding Ns is equal to zero, the voltage of the auxiliary winding Nt is induced by the voltage of the primary winding Np, and the voltage of the primary winding Np is equal to the negative voltage across the resonant capacitor Vcr, i.e., −Vcr. Although a duration indicated by a pre-charge indicating signal TonL1 (i.e., TD1 as shown in FIG. 4) is not ended, the value of the zero-crossing detecting signal Vzcd has decreased to zero. In other words, a zero-crossing time of the zero-crossing detecting signal Vzcd corresponds to the time when the voltage across the resonant capacitor Vcr crosses zero from positive to negative, the time when the resonant current Ir reaches the negative maximum value, and the time when the energy stored in the primary winding Np reaches its maximum value.

It should be appreciated that, in FIG. 2, although the resonant circuit 20 has a different structure, the zero-crossing time of the zero-crossing detecting signal Vzcd also corresponds to the time when the resonant capacitor Vcr crosses zero from positive to negative, the time when the resonant current Ir reaches the negative maximum value, and the time when the energy stored in the primary winding Np reaches its maximum value.

As illustrated above, the zero-crossing time of the zero-crossing detecting signal Vzcd corresponds to the time when the energy stored in the primary winding Np reaches the maximum value.

The zero-crossing detecting circuit 304 receives the zero-crossing detecting signal Vzcd and a zero-crossing threshold Vzth, and provides the turn-off control signal Coff to turn off the low-side switch QL when the zero-crossing detecting signal Vzcd decreases to the zero-crossing threshold Vzth. In one embodiment, the value of the zero-crossing threshold Vzth is equal or close to zero. The low-side switch control circuit 306 receives the turn-off control signal Coff and the pre-charge indicating signal TonL1, and provides the low-side switch control signal GL to turn off the low-side switch QL based on the turn-off control signal Coff and the pre-charge indicating signal TonL1. At time t2 shown in FIG. 4, the zero-crossing detecting signal Vzcd decreases to zero, the low-side switch control signal GL is pulled down to turn off the low-side switch QL.

The pre-charge indicating signal TonL1 presets a pre-charge time period TD1 of the low-side switch QL. In some embodiments, the low-side switch QL is turned on at time t1, and the low-side switch QL is turned off by the low-side switch control signal GL after the pre-charge time period TD1 indicated by the pre-charge indicating signal TonL1. However, when the zero-crossing time of the zero-crossing detecting signal Vzcd is earlier than the end time of the pre-charge time period TD1, as shown in FIG. 4, the low-side switch QL is turned off at the zero-crossing time of the zero-crossing detecting signal Vzcd rather than the end time of the pre-charge time period TD1. In other words, the low-side switch QL is turned off when: (i) the pre-charge time period TD1 indicated by the pre-charge indicating signal TonL1 ends; or (ii) the zero-crossing detecting signal Vzcd crosses zero.

In some embodiments, the pre-charge indicating signal TonL1 could be stored in a storage unit, for example, a register.

In some embodiments, the pre-charge indicating signal TonL1 could be set by users or preset by an upper-level system. For instance, the control circuit may have a data interface, the value of the pre-charge indicating signal TonL1 could be set by users or preset by the upper-level system via the data interface of the control circuit.

In some embodiments, the time when the voltage across the resonant capacitor Vcr crosses zero could be obtained by using the auxiliary winding Nt. It should be appreciated that, in other embodiments, the time when the voltage across the resonant capacitor Vcr crosses zero could be obtained by using other methods. For example, in one embodiment, the time when the voltage across the resonant capacitor Vcr crosses zero could be roughly obtained based on a resonance period Tm. The resonance period Tm could be calculated based on the inductance of the primary winding Np (the sum of Lr and Lm, wherein Lm presents a magnetizing inductance of the transformer) and the capacitance of the resonant capacitor Cr, i.e.,

$$Tm = 2 π \sqrt{( Lr + Lm ) \times Cr} .$$

The time when the on-time period of the low-side switch QL reaches a quarter of the resonance period Tm roughly corresponds to the time when the voltage across the resonant capacitor Vcr crosses zero. In practical application, it is difficult to obtain the inductance of the primary winding Np and the capacitance of the resonant capacitor Cr accurately, therefore, the time when the voltage across the resonant capacitor Vcr crosses zero obtained by the above calculation is an estimated time.

In FIG. 4, after a dead-time, at time t3, the high-side switch QH is turned on. In one embodiment, the high-side switch QH is turned on based on a slew rate of the switching voltage Vsw. For example, when the high-side switch control circuit 307 detects that the slew rate of the switching voltage Vsw decreases to zero or a preset value, the high-side switch control signal GH is provided to turn on the high-side switch QH. Other conventional circuits for detecting the slew rate of the voltage could be used in the present invention, to realize the purpose of detecting the slew rate of the switching voltage Vsw.

In FIG. 4, at time t4, when the high-side switch control circuit 307 provides the high-side switch control signal GH to turn off the high-side switch QH when it detects that the resonant current Ir reaches a preset peak value Ipk. Persons having ordinary skill in the art could set the preset peak value Ipk according to the specs and requirements of applications.

In FIG. 4, at time t5, the switching voltage Vsw decreases to zero again. The turn-on control signal Con pulls up the low-side switch control signal GL through the low-side switch control circuit 306, to turn on the low-side switch QL again.

The demagnetization detecting circuit 305 detects a demagnetization time of the transformer T1 (i.e., a time when an excitation current Im of the transformer T1 decreases to zero), and provides a demagnetization signal Dem to indicate the demagnetization time of the transformer T1. The excitation current Im of the transformer T1 (i.e., the dashed line of the top waveform in FIG. 4) decreases to bottom with a fixed slope and partially coincides with the solid line. The demagnetization detecting circuit 305 could be realized by other conventional demagnetization detecting circuits, which is not limited in the present disclosure. For example, the demagnetization signal Dem is provided by detecting the peak value of the resonant current Ir and the slope of the excitation current Im, wherein the slope of the excitation current Im is estimated according to the practical application parameters.

The low-side switch control circuit 306 receives the demagnetization signal Dem. When the demagnetization signal Dem indicates that the transformer T1 is demagnetized, i.e., time t6 in FIG. 4, the low-side switch control circuit 306 provides the low-side switch control signal GL to turn off the low-side switch QL.

In one embodiment, the low-side switch control circuit 306 further receives a resonance period Tr. The resonance period Tr could be calculated based on the inductance of the resonant inductor Lr and the capacitance of the resonant capacitor Cr, i.e.,

$$Tr = 2 π \sqrt{Lr \times Cr} .$$

When the resonance period Tr ends earlier than the demagnetization time of the transformer T1, the low-side switch QL is turned off when the resonance period Trends. In other words, the low-side switch QL is turned off by the low-side switch control signal GL when: (i) the resonance period Tr ends; or (ii) the transformer T1 is demagnetized.

In FIG. 4, at time t7, the switching voltage Vsw decreases to zero, the low-side switch QL is turned on again, and a new switching period repeats. The time period t1-t7 is a switching period of the resonant circuit 10 when it is controlled by the control circuit 30 to operate in PSM.

In a conclusion, when the resonant circuit 10 operates in PSM mode with the low output voltage Vout, the low-side switch is turned on twice in one switching period of the resonant circuit 10, which means the low-side switch control signal GL includes a first pulse (t1-t2) and a second pulse (t5-t6). The first pulse functions as a pre-charge pulse. When the low-side switch QL is turned on by the pre-charge pulse of the low-side switch control signal GL, the inductor of the primary winding Np stores the energy. When the first pulse ends and the low-side switch QL is turned off, the energy stored in the inductor of the primary winding Np is transferred to charge the switching terminal SW, thus the switching voltage Vsw is pulled up to the input voltage Vin (as close as possible), to achieve the ZVS turn-on of the high-side switch QH. The first pulse ends when one of the following conditions is met: (i) the pre-charge indicating signal TonL1 indicates that the pre-charge time period TD1 of the low-side switch QL ends; and (ii) the zero-crossing detecting signal Vzcd crosses zero from positive value to negative. After the high-side switch QH is turned off, the low-side switch QL is turned on by the second pulse after the dead-time from when the switching voltage Vsw decreases to zero again. The second pulse ends when one of the following conditions is met: (i) the resonance period Tr of the resonant circuit ends; and (ii) the transformer T1 of the resonant circuit is demagnetized.

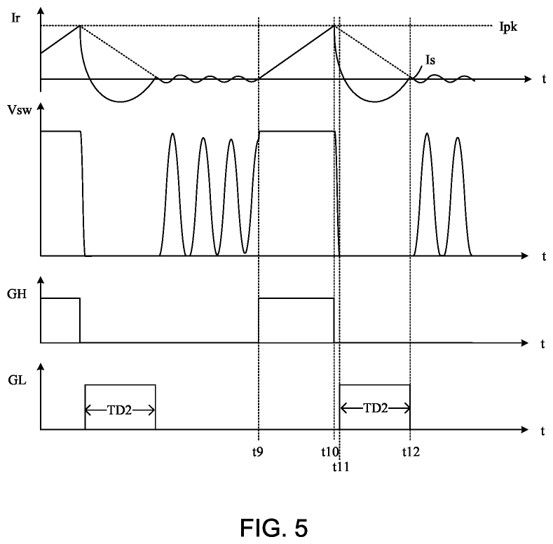

FIG. 5 shows waveforms of signals of the resonant circuit 10 operating in PSM with a high output voltage Vout in accordance with an embodiment of the present invention, which means the output voltage Vout is higher than the output voltage threshold Voth, and the power feedback signal Vfb is lower than the power threshold Vpth.

Reference will now be made to FIG. 1, FIG. 3, and FIG. 5 to describe the working principle of the control circuit 30 when the resonant circuit 10 is controlled to operate in PSM with high output voltage Vout.

At time t9, the slew rate of the switching voltage Vsw decreases to zero, the high-side switch QH is turned on, and the resonant current Ir increases. At time t10, the resonant current Ir increases to the preset peak value Ipk, the high-side switch control signal GH is provided by the high-side switch control circuit 307 to turn off the high-side switch QH. After a dead-time, at time 11, the value of the switching voltage Vsw decreases to zero, the turn-on control signal Con pulls up the low-side switch control signal GL through the low-side switch control circuit 306, to turn on the low-side switch QL. Therefore, the ZVS turn-on of the low-side switch QL could be achieved to reduce the turn-on loss. At time t11, a preset on-time period TD2 of the low-side switch QL starts. The preset on-time period TD2 is decided by an on-time period signal TonL2. In some embodiments, at time t12, the preset on-time period TD2 of the low-side switch QL ends, the low-side switch QL is turned off. When the switching period ends and the slew rate of the voltage Vsw decreases to zero again, the high-side switch QH is turned on again, and a new switching period repeats.

As shown in FIG. 5, at time t9, the high-side switch QH is turned on, but the switching voltage Vsw is lower than the input voltage Vin. In other words, the voltage across the high-side switch QH is greater than zero (i.e., Vin−Vsw>0) at the moment when the high-side switch QH is turned on, thus the turn-on loss of the high-side switch QH is still generated. However, since the voltage difference between the input voltage Vin and the switching voltage Vsw is relatively small, the turn-on loss of the high-side switch QH in the embodiment of FIG. 5 is less than or equal to the turn-on loss of the high-side switch QH in the embodiment of FIG. 4 (i.e., adopting the method of turning on the low-side switch QL firstly to pre-charge the inductor of the primary winding Np). Thus, the pre-charge process is not necessary when the resonant circuit 10 operates in PSM with the high output voltage Vout.

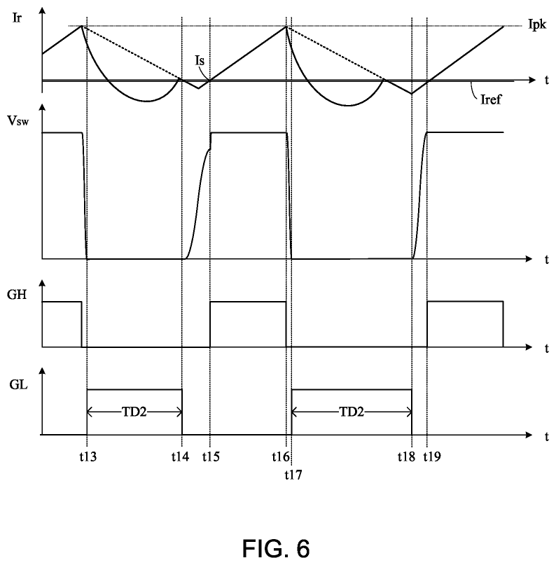

FIG. 6 shows waveforms of signals of the resonant circuit 10 operating in CCM in accordance with an embodiment of the present invention, which means the power feedback signal Vfb is larger than the power threshold Vpth.

Reference will now be made to FIG. 1, FIG. 3, and FIG. 6 to describe the working principle of the control circuit 30 when the resonant circuit 10 is controlled to operate in CCM, and the working principle of on-time period control circuit 308.

As shown in FIG. 6, at time t13, the switching voltage Vsw decreases to zero, the turn-on control signal Con pulls up the low-side switch control signal GL through the low-side switch control circuit 306, to turn on the low-side switch QL. Therefore, the ZVS turn-on of the low-side switch QL could be achieved to reduce the turn-on loss.

After the preset on-time period TD2 decided by the on-time period signal TonL2 from time t13, at time t14, the low-side switch control signal GL provided by the low-side switch control circuit 306 is pulled down to turn off the low-side switch QL. In some embodiments, when the zero-crossing time of the zero-crossing detecting signal Vzcd is earlier than the end time of the preset on-time period TD2, the low-side switch QL is turned off by the low-side switch control signal GL at the zero-crossing time of the zero-crossing detecting signal Vzcd.

At time t15, the high-side switch QH is turned on, the resonant current Ir increases. At time t16, the resonant current Ir increases to the preset peak value Ipk, the high-side switch control circuit 307 provides the high-side switch control signal GH to turn off the high-side switch QH. After a dead-time, at time t17, the switching voltage Vsw decreases to zero again, the low-side switch QL is turned on again, and a new switching period repeats.

As shown in FIG. 6, at time t15, when the high-side switch QH is turned on, the switching voltage Vsw is lower than the input voltage value Vin. In other words, when the high-side switch QH is turned on, the voltage across the high-side switch QH is greater than zero (i.e., Vin−Vsw>0), thus turn-on loss of the high-side switch QH is still generated.

In the embodiment of the present invention, the on-time period control circuit 308 detects the resonant current Ir at a moment the high-side switch QH is turned on in the present switching period, and adjusts the on-time period signal TonL2 in the next switching period based on the detected resonant current Ir.

The on-time period control circuit 308 includes a current adjustment circuit 308A and an on-time period regulating circuit 308B. The current adjustment circuit 308A receives a detected current signal Is and a charging current reference Iref, and provides an on-time period regulating signal Tcon based on the detected current signal Is and the charging current reference Iref. The on-time period regulating circuit 308B receives the on-time period regulating signal Tcon and an initial on-time period signal Toni, and provides the on-time period signal TonL2 based on the on-time period regulating signal Tcon and the initial on-time period signal Toni.

In some embodiments, the detected current signal Is corresponds to the resonant current Ir at the moment when the high-side switch QH is turned on. The charging current reference Iref corresponds to a desired value of the resonant current Ir at the corresponding time. When the absolute value of the detected current signal Is is smaller than the absolute value of the charging current reference Iref, the current adjustment circuit 308A provides the on-time period regulating signal Tcon to adjust the on-time period of the low-side switch QL. The working principle is described below. As shown in FIG. 6, at time t15, the absolute value of the resonant current Ir (i.e., the detected current signal Is) is smaller than the absolute value of the charging current reference Iref. The on-time period regulating signal Tcon is provided by the current adjustment circuit 308A. The on-time period regulating circuit 308B receives the on-time period regulating signal Tcon and the initial on-time period signal Toni indicating the on-time period of the low-side switch QL of the present switching period, and provides the regulated on-time period signal TonL2 based on the on-time period regulating signal Tcon and the initial on-time period signal Toni. Thus, the preset on-time period TD2 of the low-side switch QL of the next switching period is prolonged. As shown in FIG. 6, the time period t17-t18 is longer than the time period t13-t14. After prolonging the preset on-time period TD2 of the low-side switch QL, more energy could be stored in the primary winding Np when the low-side switch QL is turned off. After turning off the low-side switch QL, during t18-t19, the energy stored in the primary winding Np charges the switching terminal SW and the switching voltage Vsw is pulled up to the input voltage Vin, thereby the ZVS turn-on of the high-side switch QH could be achieved. In one embodiment, when the absolute value of the detected current signal Is is larger than the absolute value of the charging current reference Iref, the on-time period regulating signal Tcon shortens the on-time period of the low-side switch QL of the next switching period through regulating the on-time period signal TonL2.

In one embodiment, the value of the initial on-time period signal Toni is provided by a register. In other words, the control circuit 30 includes the register to store the initial on-time period signal Toni indicating the on-time period of the low-side switch QL of the present switching period. The on-time period of the low-side switch QL of the next switching period is calculated based on the initial on-time period signal Toni. In one embodiment, the value of the on-time period signal TonL2 is calculated based on the on-time initial value Toni and the on-time period regulating signal Tcon.

In one embodiment, the initial value of the on-time period signal TonL2 is calculated based on the peak value of the resonant current Ir and the slope of the excitation current Im of the primary side of the transformer T1 (as shown in FIG. 6). During the working process of the circuit, the on-time period of the present switching period (which is indicated by the on-time initial signal Toni) is regulated by the on-time period regulating signal Tcon to update the on-time period signal TonL2 of the next switching period. The excitation current Im is calculated based on the peak value of the resonant current Ir, the turns ratio of the primary winding Np to the secondary winding Ns, and the voltage across the secondary winding Ns, which is well known by the persons having ordinary skill in the art, and descriptions thereof are omitted here.

In one embodiment, the value of the on-time period signal TonL2 is fixed and could be set according to the specs and requirements of applications.

In one embodiment, the detected current signal Is may be the resonant current Ir at the moment when the high-side switch QH is turned on. In some embodiments, a turn-on time of the high-side switch QH (i.e., the moment that the high-side switch QH is turned on) may be before, during, or after turning on the high-side switch QH. In other embodiments, the detected current signal Is may be obtained by other conventional calculation methods. The value of the charging current reference Iref could be set according to the specs and requirements of applications.

In the embodiment of the present invention, the control circuit 30 could be realized by a digital circuit. The high-side switch control circuit 307 and the low-side switch control circuit 306 could be realized by a state machine. For instance, the digital circuit is generated automatically by using hardware description language (e.g., Verilog, VHDL). It should be appreciated that, circuit blocks in the embodiment of FIG. 3 are just for illustration purpose and do not represent the actual circuits of the present invention.

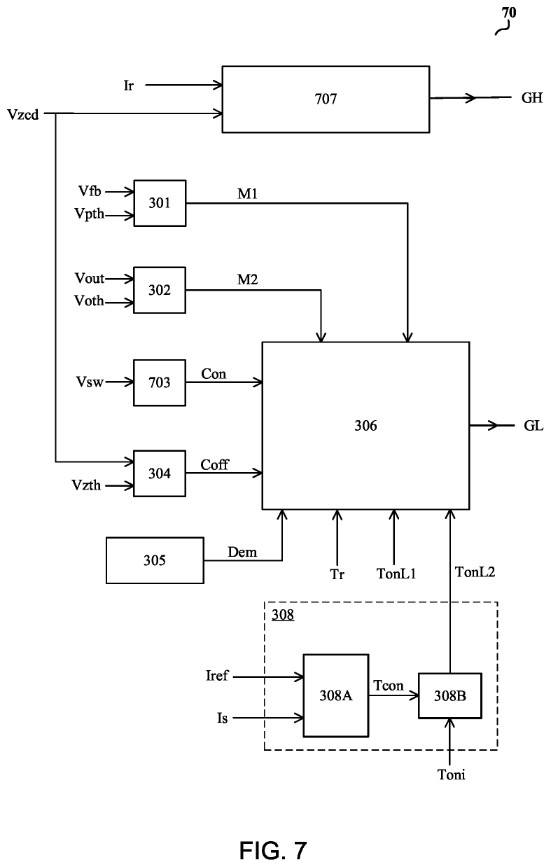

FIG. 7 schematically shows a control circuit 70 in accordance with an embodiment of the present invention. As shown in FIG. 7, the control circuit 70 includes the output power detecting circuit 301, the output voltage detecting circuit 302, a switching voltage detecting circuit 703, the zero-crossing detecting circuit 304, the demagnetizing detecting circuit 305, the low-side switch control circuit 306, a high-side switch control circuit 707, and the on-time period control circuit 308.

Compared with the embodiment of FIG. 3, in FIG. 7, the switching voltage detecting circuit 703 detects the slew rate of the switching voltage Vsw. When the slew rate of switching voltage Vsw increases from the negative value to zero, the switching voltage detecting circuit 703 provides the turn-on control signal Con to pull up the low-side switch control signal GL through the low-side switch control circuit 306 for turning on the low-side switch QL.

Compared with the embodiment of FIG. 3, in FIG. 7, the high-side switch QH is turned on by the high-side switch control circuit 707 based on the zero-crossing detecting signal Vzcd. For instance, the high-side switch QH is turned on by the high-side switch control circuit 707 after a delay from the time when a zero-crossing detecting signal crosses zero. The high-side switch control circuit 707 turns off the high-side switch QH in the same way as the high-side switch control circuit 307, i.e., the high-side switch QH is turned off based on the detection of the peak value of the resonant current Ir, and descriptions thereof are omitted here.

In the embodiment of FIG. 7, the working principles of other circuits of the control circuit 70 are the same as the control circuit 30, and descriptions thereof are omitted here.

It should be appreciated that, the switching voltage detecting circuits 303 and 703 are optional, and the high-side switch control circuits 307 and 707 are also optional. Persons having ordinary skill in the art could select the appropriate switching voltage detecting circuit and high-side switch control circuit with the reference to the embodiments of the invention for combined application. It should be appreciated that other proper control methods could be applied in the embodiments of the present invention.

In some embodiments of the present invention, when the high-side switch QH/the low-side switch QL is turned on based on the slew rate of the switching voltage Vsw, a precondition may be added to avoid the false triggering caused by ringing. In one embodiment, an interval time is set between the present turn-on time of the high-side switch QH and the previous turn-on time of the high-side switch QH, for example, a preset duration of a switching period. In another embodiment, an interval time is set between a start time of the present pre-charge time period of the low-side switch QH and a start time of the previous pre-charge time period of the low-side switch QH, for example, the preset duration of the switching period. It should be appreciated that, other methods for avoiding the false triggering could be used in the embodiments of the present invention. For instance, at time t5 in FIG. 4, when the low-side switch QL is turned on based on the slew rate of the switching voltage Vsw, the detection of a falling edge of the high-side switch control signal GH could be added as the precondition.

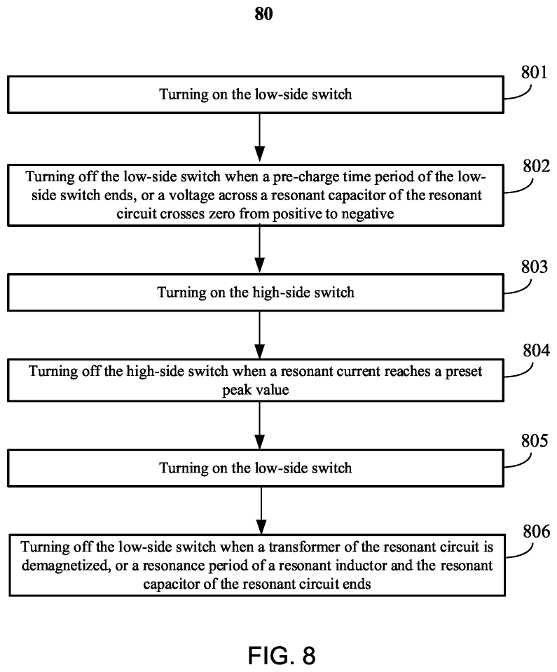

FIG. 8 schematically shows a flowchart of a control method 80 for a resonant circuit operating in PSM with a low output voltage in accordance with an embodiment of the present invention. The resonant circuit may have an asymmetric half-bridge flyback topology (as shown in FIG. 1 and FIG. 2) or other topologies, for example, LLC and LCC. The resonant circuit has a high-side switch and a low-side switch.

In some embodiments, the resonant circuit operates in PSM when an output power of the resonant circuit is lower than a power threshold. The power threshold could be set according to application requirements. The control methods 80 shows a working process of the resonant circuit 10 operating in PSM with the low output voltage Vout in one switching period. In one embodiment, the low output voltage refers that the output voltage is lower than a certain output voltage threshold. As shown in FIG. 8, the control method 80 includes steps 801-806, which are implemented in each switching period of multiple switching periods. In step 801, turning on the low-side switch. In step 802, turning off the low-side switch when a pre-charge time period of the low-side switch ends, or the voltage across the resonant capacitor crosses zero from positive to negative. In step 803, turning on the high-side switch. In step 804, turning off the high-side switch when a resonant current reaches a preset peak value. In step 805, turning on the low-side switch. In step 806, turning off the low-side switch when a transformer of the resonant circuit is demagnetized, or a resonance period of a resonant inductor and the resonant capacitor of the resonant circuit ends.

A time when the voltage across the resonant capacitor crosses zero is indicated by a zero-crossing detecting signal. In one embodiment, the zero-crossing detecting signal is obtained by using an auxiliary winding of the transformer of the resonant circuit.

In one embodiment, the low-side switch is turned on when a switching voltage decreases to a switching voltage threshold. The switching voltage is a voltage of a connection node of the high-side switch and the low-side switch. In one embodiment, the switching voltage threshold is equal or close to zero.

In one embodiment, the low-side switch is turned on based on a slew rate of the switching voltage. For example, when the slew rate of the switching voltage increases from a negative value to zero, the low-side switch is turned on.

In one embodiment, the low-side switch is turned on based on the slew rate of the switching voltage, in addition, the turning on of the low-side switch further includes a precondition: an interval time between a start time of the present pre-charge time period of the low-side switch and a start time of the previous pre-charge time period of the low-side switch should meet a certain interval duration (e.g., a preset duration of the switching period). For example, in the embodiment of FIG. 4, the interval time between the time t1 and time t7 should be equal to (or longer than) the certain interval duration.

In one embodiment, the high-side switch is turned on when the slew rate of the switching voltage decreases from a positive value to zero.

In one embodiment, the high-side switch is turned on based on the slew rate of the switching voltage, in addition, the turning on of the high-side switch further includes a precondition: an interval time between the present turn-on time of the high-side switch and the previous turn-on time of the high-side switch should meet a certain interval duration (e.g., the preset duration of the switching period).

In one embodiment, the high-side switch is turned on when the switching voltage increases to a maximum value. For example, the high-side switch is turned on when the switching voltage increases to an input voltage of the resonant circuit. It should be appreciated that, the switching voltage is difficult to increase to the input voltage under some conditions. In this case, the high-side switch is turned on when the switching voltage increases to the maximum value it could reach.

In one embodiment, the step 806 is replaced by a step 807, the step 807 includes: the low-side switch is turned off when one of the following conditions is met: (i) the transformer of the resonant circuit is demagnetized; and (ii) a resonance period of the resonant circuit ends. The resonance period is the resonance period of a resonant inductor and a resonant capacitor of the resonant circuit.

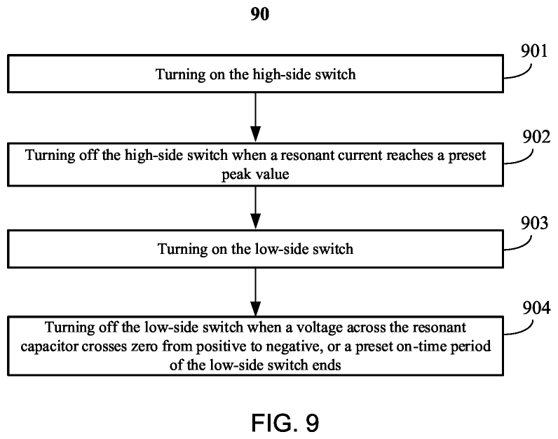

FIG. 9 schematically shows a flowchart of a control method 90 for a resonant circuit operating in CCM in accordance with an embodiment of the present invention. The resonant circuit may have an asymmetric half-bridge flyback topology (as shown in FIG. 1 and FIG. 2) or other topologies, such as LLC and LCC. The resonant circuit has a high-side switch and a low-side switch.

In some embodiments of the present invention, the resonant circuit operates in CCM when an output power of the resonant circuit is larger than a power threshold. The control methods 90 shows a working process of the resonant circuit 10 operating in CCM in one switching period. As shown in FIG. 9, the control method 90 includes steps 901-904, which are implemented in each switching period of multiple switching period. In step 901, turning on the high-side switch. In step 902, turning off the high-side switch when a resonant current reaches a preset peak value. In step 903, turning on the low-side switch. In step 904, turning off the low-side switch when a voltage across the resonant capacitor crosses zero from positive to negative, or a preset on-time period of the low-side switch ends.

In one embodiment, the high-side switch is turned on when a slew rate of a switching voltage decreases from a positive value to zero. The switching voltage is a voltage of a connection node of the high-side switch and the low-side switch.

In one embodiment, the high-side switch is turned on based on the slew rate of the switching voltage, in addition, the turning on of the high-side switch further includes a precondition: an interval time between the present turn-on time of the high-side switch and the previous turn-on time of the low-side switch should meet a certain interval duration (e.g., a preset duration of a switching period).

In one embodiment, the high-side switch is turned on when the switching voltage increases to a maximum value. For example, the high-side switch is turned on when the switching voltage increases to an input voltage of the resonant circuit. It should be appreciated that, the switching voltage is difficult to increase to the input voltage under some conditions. In this case, the high-side switch is turned on when the switching voltage increase to the maximum value it could reach.

In one embodiment, the high-side switch is turned on when the slew rate of the switching voltage increases from a negative value to zero.

In one embodiment, the low-side switch is turned on based on the slew rate of the switching voltage, in addition, the turning on of the low-side switch further includes a precondition: an interval time between the present turn-on time of the low-side switch and the previous turn-on time of the high-side switch should meet a certain interval duration.

In one embodiment, the low-side switch is turned on when the switching voltage decreases to a switching voltage threshold. The switching voltage threshold is equal or close to zero.

In one embodiment, the preset on-time period of the low-side switch is fixed, and the preset on-time period could be set according to the specs and requirements of applications.

In one embodiment, the preset on-time period is regulated based on an on-time period of the low-side switch in the previous switching period and the value of the resonant current at the moment when the high-side switch is turned on.

In one embodiment, in the previous switching period, when an absolute value of the resonant current is smaller than an absolute value of a charging reference, the on-time period of the low-side switch in the previous switching period is prolonged to be used as the preset on-time period of the low-side switch of the present switching period. In other embodiment, in the previous switching period, when the absolute value of the resonant current is larger than the absolute value of the charging reference, the on-time period of the low-side switch in the previous switching period is shortened to be used as the preset on-time period of the low-side switch of the present switching period.

Although the invention has been described with reference to several exemplary embodiments. It should be appreciated that by persons skilled in the art that the present disclosure is not limited to what has been particularly shown and described herein above. Rather the scope of the present disclosure is defined by the claims and includes both combinations and sub-combinations of the various features described hereinabove as well as variations and modifications thereof which would occur to persons skilled in the art upon reading the foregoing description and which are not in the prior art.

What is claimed is:

1. A control circuit for a resonant circuit having a high-side switch and a low-side switch, the control circuit comprising:
a low-side switch control circuit configured to provide a low-side switch control signal for controlling the low-side switch, wherein the low-side switch control signal has a first pulse associated with a first on-time period of the low-side switch, and wherein an end of the first pulse of the low-side switch control signal corresponds to a time when a voltage across a resonant capacitor of the resonant circuit crosses zero from positive to negative.

2. The control circuit of claim 1, wherein the time when the voltage across the resonant capacitor crosses zero from positive to negative is obtained by detecting a zero-crossing detecting signal, wherein the zero-crossing detecting signal is configured to be provided by an auxiliary winding of a transformer of the resonant circuit.

3. The control circuit of claim 1, further comprising:
a switching voltage detecting circuit configured to provide a turn-on control signal to the low-side control circuit for turning on the low-side switch based on a comparison result of a switching voltage threshold and a switching voltage at a connection node of the high-side switch and the low-side switch.

4. The control circuit of claim 1, further comprising:
a switching voltage detecting circuit configured to provide a turn-on control signal to the low-side control circuit for turning on the low-side switch based on a slew rate of a switching voltage at a connection node of the high-side switch and the low-side switch.

5. The control circuit of claim 1, further comprising:
a high-side switch control circuit configured to provide a high-side switch control signal to turn off the high-side switch when a current flowing through the resonant capacitor reaches a preset peak value.

6. The control circuit of claim 1, further comprising:
a high-side switch control circuit configured to provide a high-side switch control signal to turn on the high-side switch based on a slew rate of a switching voltage at a connection node of the high-side switch and the low-side switch.

7. The control circuit of claim 1, further comprising:
a high-side switch control circuit configured to provide a high-side switch control signal to turn on the high-side switch after a delay from a time when a zero-crossing detecting signal crosses zero, wherein the zero-crossing detecting signal is configured to be provided by an auxiliary winding of a transformer of the resonant circuit.

8. The control circuit of claim 1, wherein the low-side switch control circuit is further configured to receive a pre-charge indicating signal, the first pulse ends when one of following conditions is met: (i) the pre-charge indicating signal indicates that a pre-charge time period of the low-side switch ends; and (ii) the voltage across the resonant capacitor crosses zero from positive to negative.

9. The control circuit of claim 1, wherein the low-side switch control signal has a second pulse after the high-side switch is turned off, wherein the second pulse is associated with a second on-time period of the low-side switch, and wherein the second pulse ends when one of following conditions is met: (i) a resonance period of a resonant inductor and the resonant capacitor ends; and (ii) a transformer of the resonant circuit is demagnetized.

10. A resonant circuit, comprising:
a high-side switch;
a low-side switch;
a high-side switch control circuit configured to provide a high-side switch control signal for controlling the high-side switch; and
a low-side switch control circuit configured to provide a low-side switch control signal for controlling the low-side switch, wherein the low-side switch control signal has a first pulse associated with a first on-time period of the low-side switch, and wherein an end of the first pulse of the low-side switch control signal corresponds to a time when a voltage across a resonant capacitor of the resonant circuit crosses zero from positive to negative.

11. The resonant circuit of claim 10, wherein the time when the voltage across the resonant capacitor crosses zero from positive to negative is obtained by detecting a zero-crossing detecting signal, wherein the zero-crossing detecting signal is configured to be provided by an auxiliary winding of a transformer of the resonant circuit.

12. The resonant circuit of claim 10, further comprising:
a switching voltage detecting circuit configured to provide a turn-on control signal to the low-side control circuit for turning on the low-side switch based on a comparison result of a switching voltage threshold and a switching voltage at a connection node of the high-side switch and the low-side switch.

13. The resonant circuit of claim 10, further comprising:
a switching voltage detecting circuit configured to provide a turn-on control signal to the low-side control circuit for turning on the low-side switch based on a slew rate of a switching voltage at a connection node of the high-side switch and the low-side switch.

14. The resonant circuit of claim 10, wherein the high side switch control circuit is configured to turn off the high-side switch when a current flowing through the resonant capacitor reaches a preset peak value.

15. The resonant circuit of claim 10, wherein the high side switch control circuit is configured to turn on the high-side switch based on a slew rate of a switching voltage at a connection node of the high-side switch and the low-side switch.

16. The resonant circuit of claim 10, wherein the high side switch control circuit is configured to turn on the high-side switch after a delay from a time when a zero-crossing detecting signal crosses zero, wherein the zero-crossing detecting signal is configured to be provided by an auxiliary winding of a transformer of the resonant circuit.

17. The resonant circuit of claim 10, wherein the low-side switch control circuit is further configured to receive a pre-charge indicating signal, the first pulse ends when one of following conditions is met: (i) the pre-charge indicating signal indicates that a pre-charge time period of the low-side switch ends; and (ii) the voltage across the resonant capacitor crosses zero from positive to negative.

18. The resonant circuit of claim 10, wherein the low-side switch control signal has a second pulse after the high-side switch is turned off, wherein the second pulse is associated with a second on-time period of the low-side switch, and wherein the second pulse ends when one of following conditions is met: (i) a resonance period of a resonant inductor and the resonant capacitor ends; and (ii) a transformer of the resonant circuit is demagnetized.

19. The resonant circuit of claim 10, further comprising:
a transformer having a primary winding, a secondary winding, and an auxiliary winding; wherein
the resonant capacitor is coupled in series with the primary winding of the transformer.

20. A control method for a resonant circuit having a high-side switch and a low-side switch, the control method comprising:
in each switching period of multiple switching periods:
turning on the low-side switch;
turning off the low-side switch when a pre-charge time period of the low-side switch ends, or a voltage across a resonant capacitor of the resonant circuit crosses zero from positive to negative;
turning on the high-side switch;
turning off the high-side switch when a current flowing through the resonant capacitor reaches a preset peak value;
turning on the low-side switch; and
turning off the low-side switch when a transformer of the resonant circuit is demagnetized, or a resonance period of a resonant inductor and the resonant capacitor of the resonant circuit ends.

21. The control method of claim 20, wherein the low-side switch is turned on when a switching voltage at a connection node of the high-side switch and the low-side switch decreases to a switching voltage threshold.

22. The control method of claim 20, wherein the time when the voltage across the resonant capacitor crosses zero from the positive to negative is obtained by detecting a zero-crossing detecting signal, wherein the zero-crossing detecting signal is configured to be provided by an auxiliary winding of a transformer of the resonant circuit.

23. A control circuit for a resonant circuit having a first switch, a second switch, a transformer with a primary winding and a secondary winding, and a resonant capacitor coupled in series with the primary winding, the control circuit comprising:
a first switch control circuit configured to provide a first switch control signal for controlling the first switch, wherein the first switch control circuit is configured to turn off the first switch when a current flowing through the resonant capacitor reaches a preset peak value; and
a second switch control circuit configured to provide a second switch control signal for controlling the second switch, wherein the second switch control circuit is configured to turn on the second switch based on a switching voltage at a connection node of the first switch and the second switch, and further configured to turn off the second switch when a voltage across the resonant capacitor crosses zero.

24. The control circuit of claim 23, wherein the second switch control circuit comprises a zero-crossing detecting circuit configured to compare a zero-crossing detecting signal with a zero-crossing threshold to detect when the voltage across the resonant capacitor crosses zero, and wherein the zero-crossing detecting signal is configured to be provided by an auxiliary winding of the transformer.

25. The control circuit of claim 23, wherein the second switch control circuit comprises a switching voltage detecting circuit for comparing a switching voltage threshold with the switching voltage at the connection node of the first switch and the second switch.

26. The control circuit of claim 23, wherein the first switch control circuit is configured to turn on the first switch based on a slew rate of the switching voltage at the connection node of the first switch and the second switch.
